(19) United States
(12) Patent Application Publication
(10) Pub. No.: US 2024/0168052 A1
(43) Pub. Date: May 23, 2024

(54) Scanning Probe Microscope, Sample Observation Processing System, and Electric Characteristic Evaluation Device

(71) Applicant: Hitachi High-Tech Corporation, Minato-ku, Tokyo (JP)

(72) Inventors: Toru AISO, Tokyo (JP); Shuichi TAKEUCHI, Tokyo (JP); Yoshiteru SHIKAKURA, Tokyo (JP)

(21) Appl. No.: 18/283,932

(22) PCT Filed: Mar. 26, 2021
(86) PCT No.: PCT/JP2021/012775

§ 371 Date: Sep. 25, 2023

(51) Int. Cl. G01Q 30/04; G01Q 10/04; G01Q 40/00; G01Q 70/10; G01Q 80/00

(52) U.S. Cl. CPC G01Q 30/04; G01Q 10/045; G01Q 40/00; G01Q 70/10; G01Q 80/00

(57) ABSTRACT

A scanning probe microscope is designed to improve visibility of a marker in broad and high-speed observation by a magnifying observation processing device. A marker is disposed so that an aspect ratio of an observation visual field of the magnifying observation processing device is matched with an observation angle in a circumference centering on a region of interest. Further, the marker is formed by scratch scars of multiple lines, for example, to enhance edge contrast.

### TECHNICAL FIELD

The present invention relates to a scanning probe microscope device, a sample observation processing system, and an electric characteristic evaluation device having a function of forming a marker around a region of interest so that the same visual field as that of a region of interest measured using the scanning probe microscope is observed or processed with a magnifying observation processing device.

### BACKGROUND ART

Scanning probe microscopes (SPMs) forming markers such as indentations or scratch scars around regions of interest have been used to observe or process the same visual fields as the regions of interest measured using scanning probe microscopes with other magnifying observation processing devices. In general, when markers are formed around regions of interest measured using scanning probe microscopes, the marks are frequently formed at distant positions in consideration of an influence on the regions of interest. As in PTL 1 and PTL 2, to exchange needles with dedicated needles when markers are formed, deviations in positions of the markers and regions of interest at the time of exchange in probes are corrected using highly precise electric stages or special probe arrays.

### CITATION LIST

### Patent Literature

PTL 1: JP2002-139414A
PTL 2: JP2017-201304A

### SUMMARY OF INVENTION

### Technical Problem

When regions of interest measured using scanning probe microscopes are narrow regions, positions of the broad regions of interest can be specified using the markers as signs. However, when central positions of the regions of interest match rotational angles of visual fields with high accuracy using magnifying observation processing devices, it is necessary to align the vicinities of the regions of interest while observing narrow regions of magnifying observation processing devices, and thus there is a problem that the regions of interest deteriorate during the alignment. Here, the deterioration is a general term of deformation of the regions of interest of a sample due to damage of an electron beam, attachment of a carbon contamination layer to a region of interest in observation using a scanning electron microscope (SEM), charging, and the like.

Other problems and new features should be apparent from the description of the present specification and the appended drawings.

### Solution to Problem

An overview of a representative configuration of the present invention will be described below.

According to an aspect of the present invention, a scanning probe microscope is designed to improve visibility of a marker in broad and high-speed observation by a magnifying observation processing device. A marker is disposed, so that an aspect ratio of an observation visual field of the magnifying observation processing device is matched with an observation angle in a circumference centering on a region of interest. Further, the marker is formed by scratch scars of multiple lines, for example, to enhance edge contrast.

### Advantageous Effects of Invention

According to the present invention, it is possible to improve visibility of a marker even in a broad region and at high-speed observation by a magnifying observation processing device. Accordingly, even between a scanning probe microscope and a magnifying observation processing device having no highly precise electric stage, alignment of highly precise electric stages or special probe arrays is not necessary by a marker with high visibility, and a central position and a visual field angle of the region of interest can be specified easily through only broad region observation of the magnifying observation processing device. Thereafter, the region of interest can be imaged at one time at high magnification by magnification zooming of the magnifying observation processing device, and observation or processing of the region of interest or both of the observation and the processing can be performed while inhibiting deterioration in the region of interest as small as possible by the magnifying observation processing device.

### BRIEF DESCRIPTION OF DRAWINGS

FIG. 1 is an overall configuration diagram illustrating a configuration example of a scanning probe microscope of a sample scanning type according to an embodiment.

FIG. 2 is an overall configuration diagram illustrating a configuration example of a scanning probe microscope of a probe scanning type according to the embodiment.

FIG. 3 is a flowchart illustrating a procedure until observation or processing of the same location from the scanning probe microscope to the magnifying observation processing device illustrated in FIGS. 1 and 2.

FIG. 4 is a diagram illustrating Configuration Example 1 of a sample observation processing system according to the embodiment.

FIG. 5 is a diagram illustrating Configuration Example 2 of a sample observation processing system according to the embodiment.

FIG. 6 is a diagram illustrating Configuration Example 3 of a sample observation processing system according to the embodiment.

FIG. 7 is a diagram illustrating a disposition example of markers according to the embodiment.

FIG. 8 is a diagram illustrating shape examples of markers according to the embodiment.

FIG. 9 is a diagram illustrating position deviation correction before and after exchange of a marking probe.

FIG. 10 is a diagram illustrating Configuration Example 1 of a marking setting screen according to the embodiment.

FIG. 11 is a diagram illustrating Configuration Example 2 of a marking setting screen according to the embodiment.

### DESCRIPTION OF EMBODIMENTS

Hereinafter, embodiments will be described with reference to the drawings. Here, in the following description, the same constituents are denoted by the same reference numerals and repeated description thereof will be omitted in some cases. To more clarify the description, the drawings are schematically illustrated more than actual aspects, but are merely exemplary and the present invention is not construed thereto.

### EMBODIMENT

### Overall Configuration Example of Scanning Probe Microscope

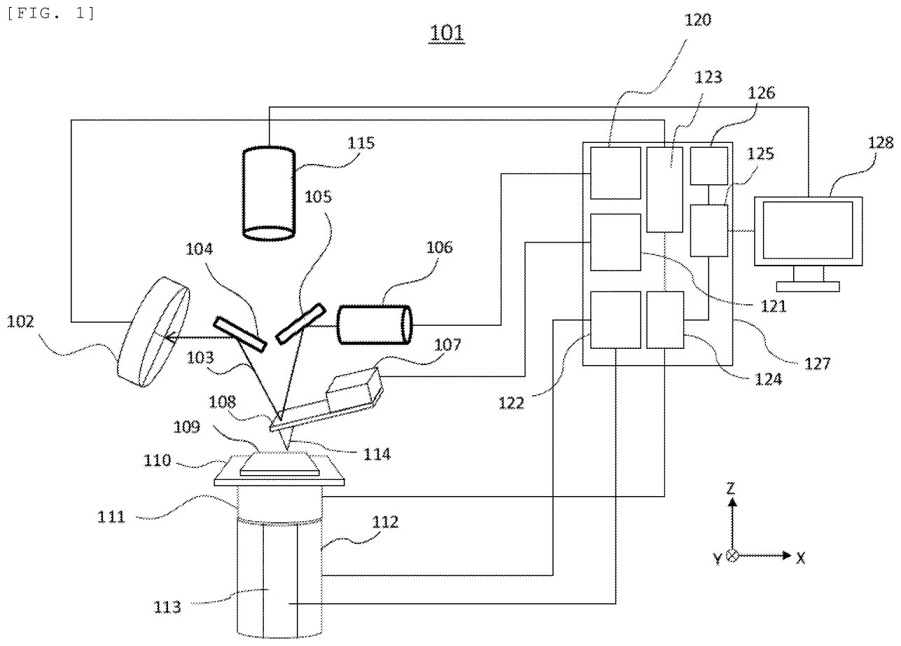

In the embodiment, a basic implementation will be described. FIG. 1 is a diagram illustrating a configuration of a scanning probe microscope (SPM) 101 of a sample scanning type according to the embodiment.

An overall operation of the scanning probe microscope 101 illustrated in FIG. 1 is controlled by a control unit 127, the rear surface of a cantilever 108 is irradiated with a laser beam 103 emitted from a laser diode 106 via a laser-side mirror 105, a needle 114 mounted on a tip end of the surface of the cantilever 108 is caused to approach the surface of a sample 109 placed on a sample table 110 by driving a sample scanner Z piezoelectric element 111. The laser diode 106 is driven by a laser control circuit 120 so that the laser beam 103 is emitted. The cantilever 108 is bent by a force acting between the needle 114 and the sample 109, so that an incident position of the laser beam 103 incident on the photodetector 102 via a detector-side mirror 104 is changed. A change in the incident position is amplified by a signal amplification circuit 123 and the sample scanner Z piezoelectric element 111 is expanded and contracted in a Z direction (the up and down directions) by a Z feedback circuit 124 so that the force typically acting between the needle 114 and the sample 109 is kept as a minute force, and an application voltage of the sample scanner Z piezoelectric element 111 is converted into height information by a signal processing unit 125. The height information is stored in a storage unit 126.

The sample 109 is scanned in an X direction (right and left directions) and a Y direction (front and rear directions) driven by an XY piezoelectric driving circuit 122 by the sample scanner X piezoelectric element 112 and a sample scanner Y piezoelectric element 113, and scanned information is converted into 3-dimensional information in conjunction with an application voltage of the sample scanner Z piezoelectric element 111 by the signal processing unit 125. The 3-dimensional information is displayed as an image of a measurement visual field measured using the scanning probe microscope 101 on a monitor display unit 128. Also, a scheme of applying an alternating-current signal from a bimorph piezoelectric driving circuit 121 to a bimorph piezoelectric element 107 and scanning the sample 109 while oscillating the cantilever 108 is also used in order to inhibit abrasion of the tip end of the needle 114.

A coarse adjustment mechanism capable of moving one of the cantilever 108 or the sample table 110 manually or electrically so that relative positions of the needle 114 and the sample 109 can be changed is included in some cases. The relative positions are adjusted using an optical microscope 115 disposed immediately above the cantilever 108.

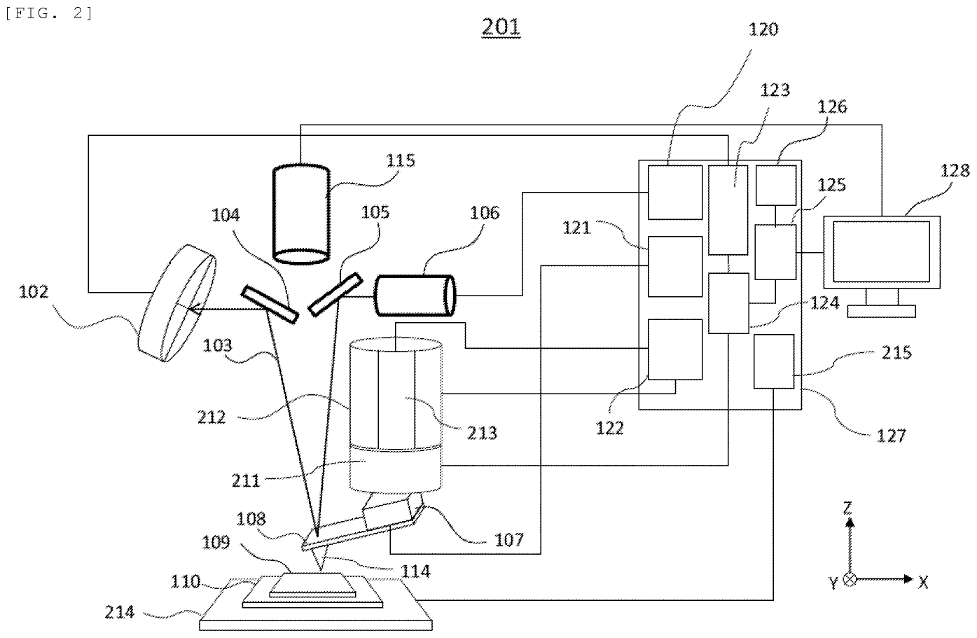

FIG. 2 is a diagram illustrating a configuration example of a scanning probe microscope 201 of a probe scanning type according to the embodiment. In the scanning probe microscope of a probe scanning type (hereinafter abbreviated to an SPM in some cases) 201, unlike the scanning probe microscope 101 of the sample scanning type, a probe scanning Z piezoelectric element 211, a probe scanning X piezoelectric element 212, and a probe scanning Y piezoelectric element 213 are on the side of the cantilever 108, and data is acquired by scanning the needle 114. The other configuration and functions of the scanning probe microscope 201 of the probe scanning type are the same as the configuration and functions of the scanning probe microscope 101 of the sample scanning type, and repeated description thereof will be omitted.

In this case, a method of simultaneously scanning all or some of the laser diode 106, the laser-side mirror 105, and the detector-side mirror 104, and the photodetector 102 and synchronizing the laser beam 103 with a scanning operation of the cantilever 108 is used. A sample stage 214 can be driven manually or by a sample stage driving circuit 215.

### (Flowchart)

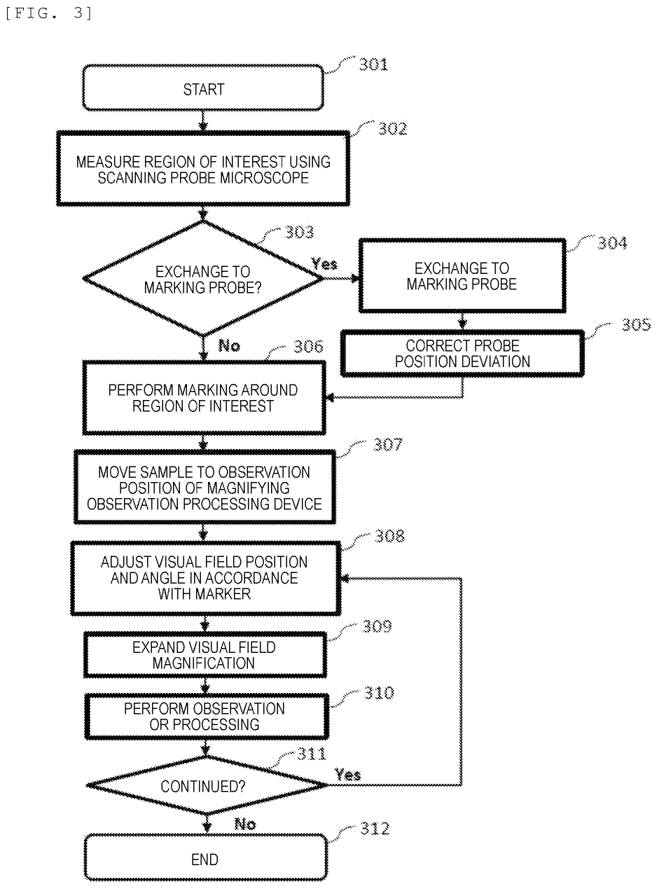

FIG. 3 is a flowchart illustrating a procedure until observation or processing or both observation and the processing of the same location from the scanning probe microscope to a magnifying observation processing device illustrated in FIGS. 1 and 2. An implementation method according to the present invention will be described with reference to the flowchart of FIG. 3.

The flowchart starts in step 301. In step 302, a region of interest is measured using the scanning probe microscope (101 or 102). Subsequently, it is determined, in step 303, whether a measurement probe including an observation needle of the scanning probe microscope is exchanged with a marking probe including a marking needle. When the measurement probe is exchanged with the marking probe in step 303 (Yes), the process proceeds to step 304. When marking is performed with the measurement probe measuring a region of interest, that is, the measurement probe is used together as the marking probe (No), the process proceeds to step 306.

When the marking is performed, marking with high visibility is performed. Therefore, the measurement probe is exchanged with the marking probe in some cases. At that time, since a needle position is deviated after the exchange of the probe, as illustrated in step 305, the deviation of the needle position is corrected by comparing data obtained by scanning an optical microscope image or a sample surface. That is, the scanning probe microscope (101 or 102) includes means for correcting positional deviation between the observation needle of the measurement probe and the marking needle of the marking probe when the measurement probe is exchanged with the marking probe.

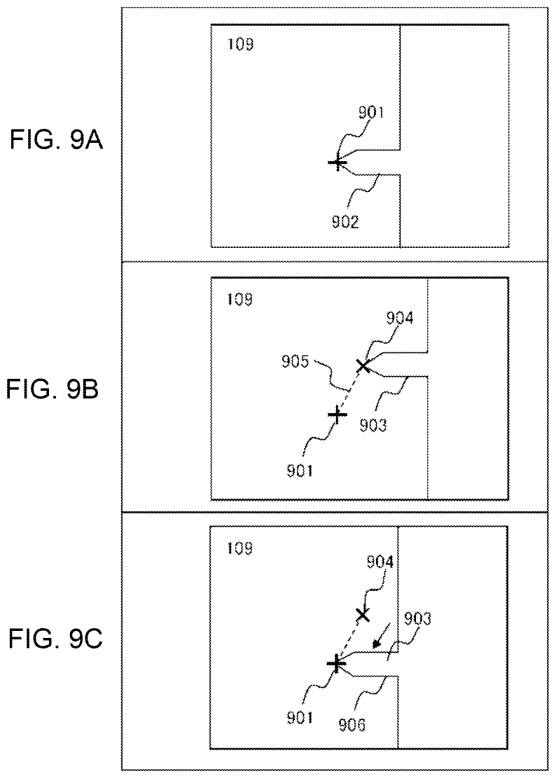

Next, a method for position deviation correction will be described with reference to FIG. 9. FIG. 9 is a diagram illustrating position deviation correction before and after exchange of a marking probe. FIG. 9 illustrates an example of position deviation correction using an optical microscope image. (a), (b), and (c) of FIG. 9 all illustrate optical microscope images of the optical microscope 115 attached immediately above the cantilever 108 of the scanning probe microscope (101 or 102). (a) of FIG. 9 illustrates an optical microscope image immediately after a region of interest is measured using the measurement probe 902. (b) of FIG. 9 illustrates an optical microscope image immediately after the measurement probe 902 is exchanged with a marking probe 903. (c) of FIG. 9 illustrates an optical microscope image when a measurement probe needle position 901 is matched with a marking probe needle position 904.

First, as illustrated in (a) of FIG. 9, the measurement probe needle position 901 is stored in the storage unit 126 by clicking the measurement probe needle position 901 with a pointing device such as a mouse in the optical microscope image immediately after the region of interest is measured using the measurement probe 902. Subsequently, as illustrated in (b) of FIG. 9, a marking probe needle position deviation distance 905 which is a distance between the measurement probe needle position 901 and the marking probe needle position 904 is measured by clicking the marking probe needle position 904 on an optical microscope image with a pointing device immediately after the measurement probe 902 is exchanged with the marking probe 903. Finally, relative positions of the marking probe 903 and the sample 109 are moved, so that the distance 905 is corrected, that is, the measurement probe needle position 901 matches the marking probe needle position 904 and the distance 905 is substantially zero. In this method, the marking probe 903 side and the sample 109 side are moved in some cases. (c) of FIG. 9 illustrates a state in which the marking probe 903 side is moved in a direction of a left oblique lower side, as indicated by an arrow, so that the needle position 904 of the marking probe 903 side overlaps the recorded measurement probe needle position 901. Here, reference numeral 906 denotes a marking probe after the position deviation correction.

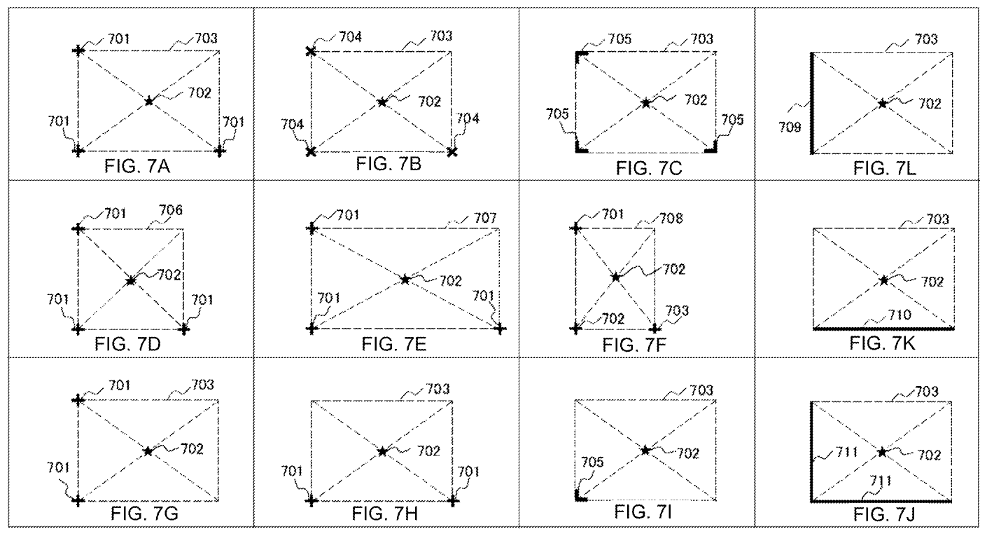

Next, in step 306 of FIG. 3, the scanning probe microscope (101 or 102) is used to perform marking around the region of interest. A marker disposition example is illustrated in FIG. 7. FIG. 7 is a diagram illustrating a marker disposition example in the scanning probe microscope (SPM) according to the embodiment. Each marker illustrated in FIG. 7 is provided to inhibit deterioration in the region of interest by observing a narrow region of the magnifying observation processing device and to specify a position of the region of interest easily while maintaining a broad region observation state of the magnifying observation processing device. Hereinafter, disposition examples of markers illustrated in (a) to (j) of FIG. 7 will be described. Here, a vicinity of a region of interest corresponds to an outer edge of a region of an observation visual field (703) in a marking search of the magnifying observation processing device.

As illustrated in (i) of FIG. 7, a marker 705 is generated to indicate at least a part of the outer edge of a region of the pre-designated observation visual field 703 in the marking search of the magnifying observation processing device, so that a region of interest 702 is located at a scaling center when the region of interest 702 is observed with the magnifying observation processing device. At this time, as illustrated in (i) of FIG. 7, it is assumed that a visual field aspect ratio of the observation visual field 703 of the magnifying observation processing device is 4:3. Further, a rectangle is identical or similar to the observation visual field 703 in the marker search of the magnifying observation processing device and a corner bracket (L-shaped) marker 705 is generated so that the rectangle indicates at least one corner. By disposing a marker at a position which is not rotationally symmetric (non-rotational target position) when the center of the region of interest 702 is a rotational center as in the corner bracket marker 705, it is possible to match angles of the region of interest 702 and the observation visual field 703 of the magnifying observation processing device.

Even when the observation visual field 703 in the marker search of the magnifying observation processing device is determined in advance, to clarify the size of the observation visual field 703, disposition of (g) of FIG. 7 in which two corners are indicated by cross markers 701 (disposition of the cross markers 701 at two points of the corners of a left short side) and (h) (disposition of the cross markers 701 at two points of the corners of a lower long side), disposition of (l) of FIG. 7 of a short-side marker 709 indicating one left short side of the observation visual field 703 in the marking search of the magnifying observation processing device, disposition of (k) of FIG. 7 of a long-side marker 710 indicating one lower long side, and disposition of (j) of FIG. 7 of a short-side and long-side integrated marker 711 indicating both of one left short side and one lower long side are also effective. Further, (a) of FIG. 7 in which three corners of the observation visual field 703 in the marker search of the magnifying observation processing device are indicated by the cross markers 701, (b) of FIG. 7 in which the three corners are indicated by cross (X type) markers 704, or (c) of FIG. 7 in which the three corners are indicated by the corner bracket markers 705 may be used.

In accordance with disposition of (d) of FIG. 7 in the case of an observation visual field 706 with a 1:1 aspect ratio in the magnifying observation processing device, disposition of (e) of FIG. 7 in the case of an observation visual field 707 with a 16:9 aspect ratio in the magnifying observation processing device, or disposition of (f) of FIG. 7 in the case of an observation visual field 708 with a 3:4 aspect ratio in the magnifying observation processing device, and an aspect ratio of the observation visual field of the magnifying observation processing device, it is preferable to be capable of setting any disposition of marking.

Here, the scanning probe microscope 101 or 102 can be summarized as follows. The scanning probe microscope 101 or 102 includes scanning units (for example, 111 to 113 or 211 to 213) scanning the sample 109 and the needle 114 relatively and observes the sample 109 by scanning the sample 109 and the needle 114. The scanning probe microscope 101 or 102 includes the control unit 127. The control unit 127 is a magnifying observation processing device that acquires the region of interest 702 obtained as a result of the scanning and then performs observation or processing or both the observation and the processing. Based on information (for example, a visual field size, a visual field aspect ratio, a visual field magnification, an observation angle, and the like of the observation visual field 703) regarding the magnifying observation processing device separated from the scanning probe microscope 101 or 102, the control unit 127 performs control such that a marker indicating at least a part of an outer edge (for example, a corner, a short side, a long side, or the like) of an observed or processed region (the observation visual field 703) is formed by specifying a region (a region of the observation visual field 703) that is a region where a region observed or processed by the magnifying observation processing device contains the region of interest 702 and is an observed or processed region (the region of the observation visual field 703) where the region of interest 702 is located at a scaling center when the region (the region of the observation visual field 703) is observed with the magnifying observation processing device, and interacting the needle 114 and the sample 109.

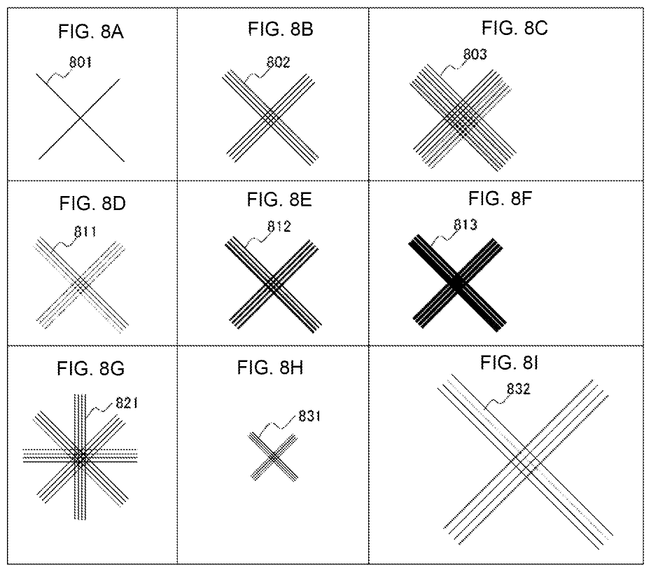

Since deterioration in the region of interest is inhibited by observing a narrow region of the magnifying observation processing device and a position of the region of interest is specified easily while maintaining a broad region observation state of the magnifying observation processing device, a level of visibility of a marker itself in the magnifying observation processing device is also important. FIG. 8 is a diagram illustrating shape examples of markers formed by the scanning probe microscope according to the embodiment. In FIG. 8, a shape example of the cross (X type) marker 704 will be described as a representative example, but shapes of the other markers (701, 705, 709, 710, and 711) can also be applied. Examples of the marker shapes will be described with reference to (a) to (i) of FIG. 8.
(a) of FIG. 8 illustrates one-line marker (one-line scratch scar) 801 formed on the sample 109 due to a scratch scar of the needle 114 of the scanning probe microscope (101 or 102). When visibility of one-line marker 801 illustrated in (a) of FIG. 8 is not sufficient, visibility of the marker can also be selectively improved by multi-line scratch scars by increasing the number of lines as in a four-lines marker 802, as illustrated in (b) of FIG. 8, and further an eight-lines marker 803, as illustrated in (c) of FIG. 8. (d) of FIG. 8 illustrates a weak tactile pressure marker 811 when a scratch scar of the needle 114 of the scanning probe microscope (101 or 102) is added on the sample 109 by a weak pressure. In the weak tactile pressure marker 811, as illustrated in (d) of FIG. 8, it is conceivable that visibility is not sufficient even when the lines themselves are thin and the number of lines is large in some cases. In these cases, a scanning speed of the needle 114 to the sample 109 can be adjusted or a strong tactile pressure marker 812 by a scratch scar in a state in which an indentation amount of the needle 114 on the sample 109 is increased as illustrated in (e) of FIG. 8 can also be set. Further, as illustrated in (f) of FIG. 8, to form the scratch scars deeply and thickly, any number of overwrites (for example, three times) can be set as in a plural-overwritten marker 813 in which deep scratch scars are formed by performing scratches at the same position repeatedly a plurality of times by the needle 114. As illustrated in (g) of FIG. 8, an asterisk marker 821 in which the number of scratches is further increased can also be set. The size of the marker itself can also be set to any size depending on a situation, as in a small-sized marker 831 illustrated in (h) of FIG. 8, a large-sized marker 832 illustrated in (i) of FIG. 8, or the like.

When the scanners (111 to 113 or 211 to 213) of the scanning probe microscope (101 or 102) include piezoelectric elements, a marker shape is distorted due to characteristics of the piezoelectric elements in some cases. In these cases, when marking is performed by the needle 114, it is preferable to perform scanning a plurality of times with the needle 114 by the scanners (111 to 113 or 211 to 213) and perform predetermined marking on the sample 109 by the needle 114 after performing the scanning by the needle 114 the plurality of times in a condition that the sample 109 is not marked by a space or the needle 114 (a condition that the marker is not formed on the sample 109 by the needle 114). Accordingly, it is possible to reduce the distortion of the marker shape. In this way, it is also possible to set to decrease the distortion of the marker shape.

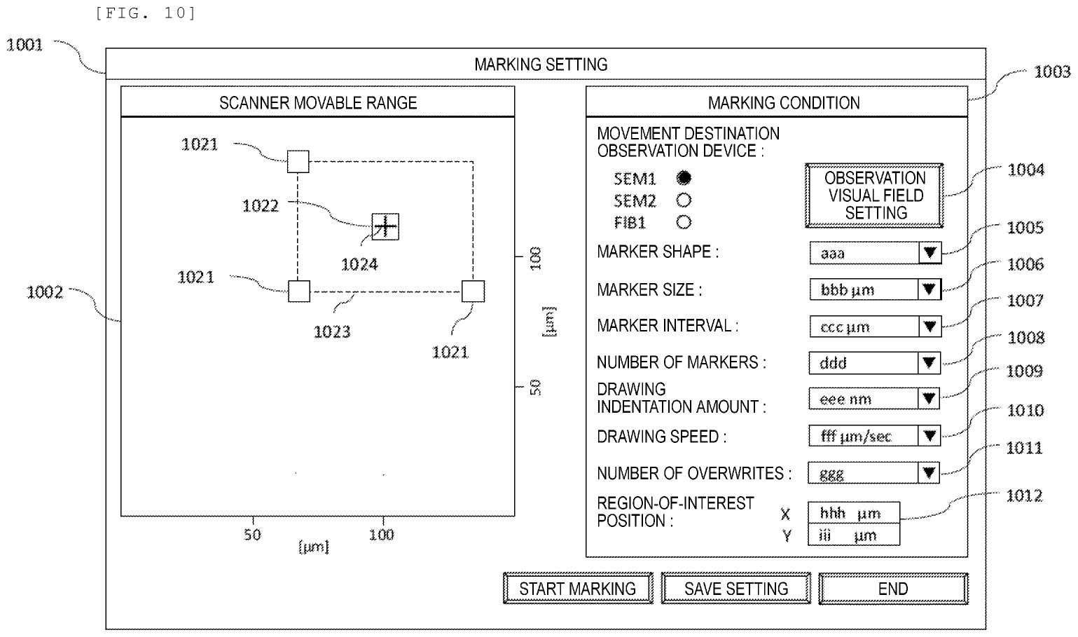

Next, a marking setting screen will be described with reference to FIG. 10. FIG. 10 is a diagram illustrating Configuration Example 1 of the marking setting screen provided in the scanning probe microscope (SPM) according to the embodiment. In FIG. 10, a case (for example, see (a) of FIG. 7) where markers are formed at three corners of the observation visual field 703 will be described as a representative example. However, other disposition examples ((g), (h), (i), (l), (k), and (j) of FIG. 7) can also be applied.

After a user specifies a region of interest using the SPM (101 or 102) and acquires an observation image, a marking setting screen 1001 is displayed on the monitor display unit 128. The marking setting screen 1001 includes a scanner movable range display portion 1002 and a marking condition display portion 1003 of the SPM. In the scanner movable range display portion 1002, an observation visual field 1022 and a region of interest 1024 of the SPM are displayed, and scanner coordinates of the region of interest 1024 are displayed at a region-of-interest position 1012.

The user selects a type of magnifying observation processing device in the marking condition display portion 1003. In this example, one device can be selected as the magnifying observation processing device among three devices including a first scanning electron microscope SEM1, a second scanning electron microscope SEM2, and a focused ion beam device FIB1. FIG. 10 illustrates a state in which the first scanning electron microscope SEM1 is selected (a black circle • mark). Although not particularly limited, the first scanning electron microscope SEM1 can be configured as a device in which a magnification of the observation visual field is the same as, or higher or lower than that of the second scanning electron microscope SEM2.

When the type of magnifying observation processing device is selected, the observation visual field 703 and an aspect ratio of the observation visual field 703 in searching of the marker by the magnifying observation processing device (here, the selected first scanning electron microscope SEM1) registered in advance by the user clicking an observation visual field setting button 1004 or acquired through communication are read, and a marking position (a disposition position condition of the marker) suitable for a visual field size of the observation visual field 703 as illustrated in (a) of FIG. 7 to (j) of FIG. 7 is determined. The user can designate a marker shape illustrated from (g) of FIG. 8 to (j) of FIG. 8 by selecting an interval at which the markers are disposed from a marker interval list box 1007 or inputting a numerical value, selecting a marker shape from a marker shape list box 1005 or inputting a numerical value, and selecting the size of a marker from a marker size list box 1006 or inputting a numerical value. When such conditions are set in the marking condition display portion 1003, a marking location 1021 based on the designated marking condition and the observation visual field 1023 of the first scanning electron microscope SEM1, which is a magnifying observation processing device, are displayed in, for example, a dotted rectangle inside the scanner movable range display portion 1002. The user confirms the scanner movable range display portion 1002 and then clicks a marking start button to start marking. When a setting save button is clicked, the marking condition set in the marking condition display portion 1003 or a display image of the scanner movable range display portion 1002 can be stored in, for example, the storage unit 126. When an end button is clicked, the display of the marking setting screen 1001 ends.

Before the marking is started, each condition to be described below may be set in the marking condition display portion 1003. The user can designate the number of marker lines, as illustrated from (a) of FIG. 8 to (c) of FIG. 8, by selecting the number of marker lines from a number-of-markers list box 1008 or inputting a numerical value. The user can set a condition for optimizing visibility of the marker in the magnifying observation processing device in the marking condition display portion 1003, as illustrated from (d) of FIG. 8 to (f) of FIG. 8, by selecting an indentation amount of the cantilever 108 (or the needle 114) in drawing of the marker from a drawing indentation amount list box 1009 or inputting a numerical value, selecting a marker drawing speed (a movement speed of the cantilever 108 (or the needle 114)) from a drawing speed list box 1010 or inputting a numerical value, and selecting the number of times the marker is overwritten from a number-of-overwrites list box 1011 or inputting a numerical value. Accordingly, since the visibility of the marker can be optimized, the visibility of the marker can be improved. The configuration example in which the condition setting list boxes 1005 to 1011 for forming the marker are provided in the marking condition display portion 1003 has been described, but an embodiment of the present invention is not limited thereto. A marker formation condition that the visibility of the marker can be improved may be able to be input or set in the marking condition display portion 1003.

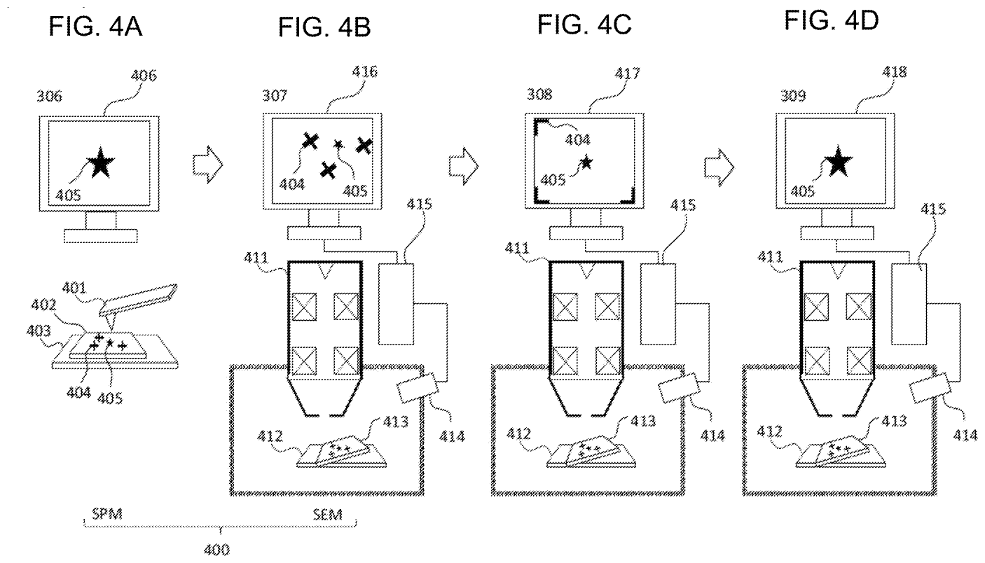

Next, a configuration example of a sample observation processing system will be described with reference to FIG. 4. FIG. 4 is a diagram illustrating Configuration Example 1 of the sample observation processing system according to the embodiment. A sample observation processing system 400 includes the magnifying observation processing device and the scanning probe microscope (SPM) in FIG. 1 or 2. FIG. 4 illustrates the sample observation processing system 400 when the magnifying observation processing device is a scanning electron microscope (SEM).
(a) of FIG. 4 illustrates a measurement visual field 406 of a scanning probe microscope (SPM) immediately after markers 404 at three points are formed around a region of interest 405 measured on the surface of a sample 402 provided on a sample table 403 using a marking probe 401 of the SPM (step 306 of FIG. 3).

In step 307 of FIG. 3, a sample provided in the scanning probe microscope (SPM) is moved to an observation position of the magnifying observation processing device, and an immediately subsequent state is illustrated in (b) of FIG. 4. Incident electrons emitted from a column 411 of a scanning electron microscope (SEM) are emitted to a sample 413 fixed on a sample stage 412 of the SEM, secondary electrons or reflected electrons generated from the vicinity of an irradiated portion are detected by a detector 414 of the SEM and are processed by a signal processing unit 415 of the SEM, and an observation visual field 416 of the SEM is displayed on a monitor.

Subsequently, in step 308 of FIG. 3, a visual field position and angle of the scanning electron microscope (SEM) are adjusted in accordance with the marker, and an adjusted state is illustrated in (c) of FIG. 4. A marker 404 is disposed at an angle of visibility, as shown in an observation visual field 417 of the SEM after the adjustment of the visual field position and angle, through driving of the sample stage 412 of the SEM or scanning angle adjustment.

Subsequently, in step 309 of FIG. 3, an observation visual field 418 is magnified by increasing a visual field magnification of the scanning electron microscope (SEM), and the magnified observation visual field 418 of the SEM in (d) of FIG. 4 can be displayed with the same size as the measurement visual field 406 of the scanning probe microscope (SPM).

Subsequently, in step 310 of FIG. 3, one or both of observation and processing of the region of interest 405 are performed. When there is another region of interest (in the case of Yes in step 311 of FIG. 3), as illustrated in step 311 of FIG. 3, the visual field position of the scanning electron microscope (SEM) can be moved to a position of the marker provided around a subsequent region of interest, and the subsequent region of interest can be repeatedly observed. When observation of all the regions of interest ends (in the case of No in step 311 of FIG. 3), the process proceeds to step 312 of FIG. 3 and the flowchart of FIG. 3 ends.

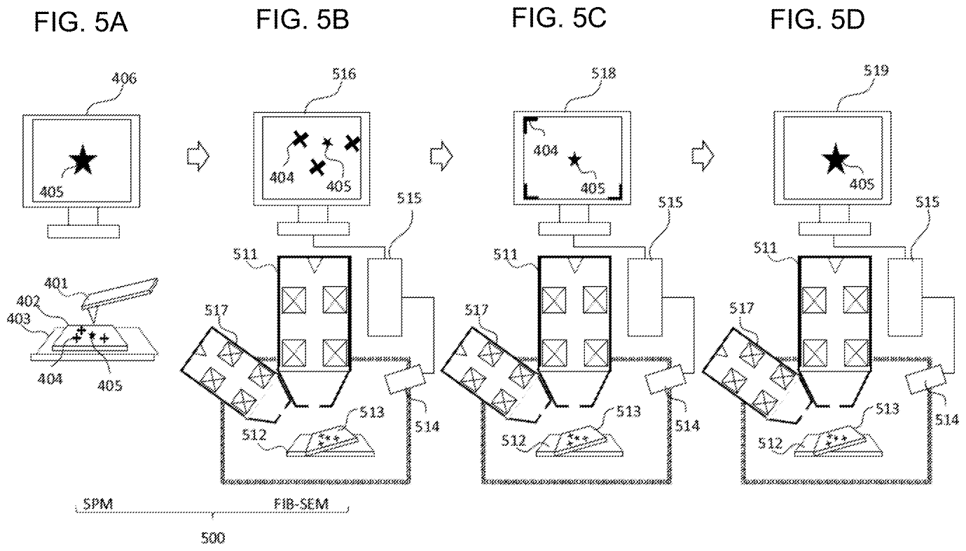

Next, another configuration example of a sample observation processing system will be described with reference to FIG. 5. FIG. 5 is a diagram illustrating Configuration Example 2 of the sample observation processing system according to the embodiment. A sample observation processing system 500 includes a magnifying observation processing device and a scanning probe microscope (SPM) in FIG. 1 or 2. FIG. 5 illustrates the sample observation processing system 500 when the magnifying observation processing device is a scanning electron microscope/focused ion beam combined device (FIB-SEM). FIG. 5 illustrates a case where a sample is moved from the scanning probe microscope (SPM) to the scanning electron microscope/focused ion beam combined device (FIB-SEM) and observation or processing or both the observation and the processing are performed on the same location in a region of interest.

As illustrated in (a) of FIG. 5, the region of interest 405 in the scanning probe microscope (SPM) is specified and three markers 404 are formed around the region of interest 405. After the three markers 404 are formed, as illustrated in (b) of FIG. 5, a sample 513 in which the markers 404 at three points are formed is provided on a sample stage 512 of the FIB-SEM. Incident electrons emitted from a column 511 of a scanning electron microscope (SEM) are emitted to a sample 513 fixed on a sample stage 512 of the FIB-SEM, secondary electrons or reflected electrons generated from the vicinity of an irradiated portion are detected by a detector 514 of the FIB-SEM and are processed by a signal processing unit 515 of the FIB-SEM, and an observation visual field 516 of the FIB-SEM is displayed on a monitor.

Next, a state after the visual field position and angle are adjusted in accordance with the marker is illustrated in (c) of FIG. 5. The marker 405 is disposed in a visual field angle, as shown in an observation visual field 518 of the FIB-SEM after the adjustment of the visual field position and angle, through driving of the sample stage 512 of the FIB-SEM or the adjustment of the scanning angle. Subsequently, the observation visual field 518 of the FIB-SEM can be magnified and displayed with the same size as the measurement visual field 406 of the SPM, as in a magnified observation visual field 519 of the FIB-SEM in (d) of FIG. 5. Thereafter, observation or processing of the region of interest 405 or both the observation and the processing can be performed with an ion beam emitted from a column 517 of a focused ion beam device (FIB).

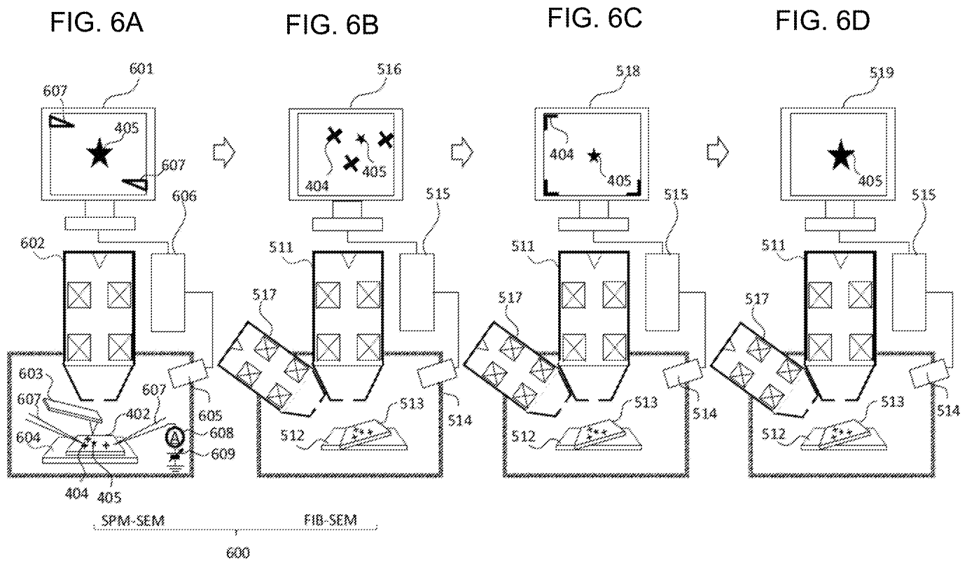

Next, still another configuration example of a sample observation processing system will be described with reference to FIG. 6. FIG. 6 is a diagram illustrating Configuration Example 3 of the sample observation processing system according to the embodiment. A sample observation processing system 600 includes a scanning probe microscope and a magnifying observation processing device. In FIG. 6, the scanning probe microscope is considered as a scanning probe microscope/scanning electron microscope (SPM-SEM) combined device. The sample observation processing system 600 in a case where the magnifying observation processing device is considered as a scanning electron microscope/focused ion beam (FIB-SEM) combined device is illustrated.

FIG. 6 illustrates a case where a sample is moved from a scanning probe microscope/scanning electron microscope (SPM-SEM) combined device in which one or a plurality of scanning probe microscopes are provided in a charged particle beam device (in this example, a scanning electron microscope) to a scanning electron microscope/focused ion beam (FIB-SEM) combined device, and observation or processing or both the observation and the processing are performed on the same location in a region of interest. In a sample chamber of the scanning probe microscope/scanning electron microscope (SPM-SEM) combined device, one or more conductive probes 607 and a marking probe 603 of the scanning probe microscope (SPM) are disposed around the sample 402. The conductive probe 607 is provided for electric measurement. The scanning probe microscope/scanning electron microscope (SPM-SEM) combined device has a function of scanning the sample 402 using the probes 607 and 603, evaluating electric characteristics of minute semiconductor elements formed on the sample 402 using an ammeter 608 or a constant voltage source 609 fixed to a certain specific position, or forming the marker 404 around the region of interest 405. That is, the scanning probe microscope/scanning electron microscope (SPM-SEM) combined device includes a minute semiconductor element characteristic evaluation device.
(a) of FIG. 6 is a configuration diagram of the SPM-SEM combined device. Incident electrons emitted from a column 602 of the scanning electron microscope (SEM) of the SPM-SEM combined device are emitted to the sample 402 fixed onto a sample stage 604 of the SPM-SEM combined device, secondary electrons or reflected electrons generated from the vicinity of an irradiated portion are detected by a detector 605 of the SPM-SEM combined device and are processed by a signal processing unit 606 of the SPM-SEM combined device, and an observation visual field 601 of the SPM-SEM combined device is displayed on a monitor. In the observation visual field 601 of the SPM-SEM combined device, a position of the region of interest 405 or the marker 404 or a motion or a fixed position of the conductive probe 607 or the marking probe 603 is displayed. The marker 404 is formed around the specified region of interest 405 of the sample 402 using the marking probe 603 provided inside the SPM-SEM combined device, the sample 402 in which the marker 404 is formed is subsequently moved to the sample stage 512 of the SPM-SEM combined device, and observation or processing of the region of interest 405 or both the observation and the processing are performed. Since (b), (c), and (d) of FIG. 6 are the same as (b), (c), and (d) of FIG. 5, repeated description will be omitted. As illustrated in FIG. 6, the sample observation processing system 600 can also be constructed.

The scanning probe microscope/scanning electron microscope (SPM-SEM) combined device will be further described. As described above, the scanning probe microscope/scanning electron microscope (SPM-SEM) combined device has a function of an electric characteristic evaluation device that evaluates electric characteristics of the sample 402. An electric measurement probe 607 can be said to be a conductive needle. The scanning probe microscope/scanning electron microscope (SPM-SEM) combined device includes driving units (111 to 113 or 211 to 213) that change a relative position relation between the sample 402 and the needle 607, as described in FIGS. 1 and 2, an electric characteristic evaluation unit (608 or 609) that is connected to the needle 607 and evaluates electric characteristics of the sample 402, and a charged particle beam irradiation unit 602 that irradiates the sample 402 with a charged particle beam.

The scanning probe microscope/scanning electron microscope (SPM-SEM) combined device evaluates electric characteristics of the sample 402 by irradiating the sample 402 with a charged particle line while bringing the needle 607 to come into contact with the sample 402. Alternatively, the needle 607 of the scanning probe microscope/scanning electron microscope (SPM-SEM) combined device can be brought int contact with the sample 402 within a visual field of the charged particle beam irradiation unit 602, and electric characteristics of the sample 402 are evaluated by irradiating the sample 402 with the charged particle beam while bringing the needle 607 into contact with the sample 402. For example, the electric characteristics of the sample 402 are evaluated by measuring a current or a voltage or both the current and the voltage generated in a semiconductor element or a wiring formed in the sample 402 by being irradiated with a charged particle beam via the needle 607.

Then, the scanning probe microscope/scanning electron microscope (SPM-SEM) combined device specifies the region of interest 405 of the sample 402 based on a result of the evaluation of the electric characteristics. The region of interest 405 can be, for example, a region including a disconnected portion of a wiring, a region including a breakdown portion of a semiconductor element or a wiring, a region including a foreign substance portion on the sample 402, a region including a portion satisfying a predetermined condition or a portion not satisfying the predetermined condition, or the like. The scanning probe microscope/scanning electron microscope (SPM-SEM) combined device forms the marker 404 indicating at least a port of an outer edge of an observed or processed region by specifying a region that is a region containing the region of interest 405 and is an observed or processed region where the region of interest 402 is located at a scaling center when the region is observed with the magnifying observation processing device (FIB-SEM) and interacting the needle 607 and the sample 402.

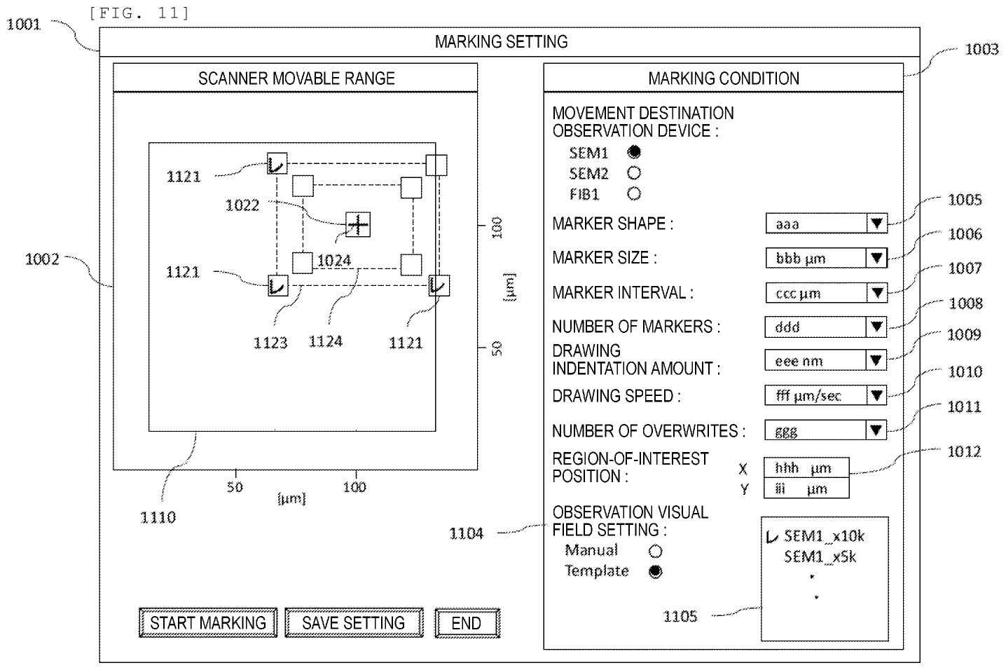

Next, a modification of the marking setting screen will be described with reference to FIG. 11. FIG. 11 is a diagram illustrating Configuration Example 2 of the marking setting screen according to the embodiment. Differences of FIG. 11 from FIG. 10 are that an observation visual field setting region 1104 is provided in the marking condition display portion 1003 instead of the observation visual field setting button 1004, a marking location designation portion 1121 that is selectable to designate a marking location is displayed inside the scanner movable range display portion 1002, and an observation visual field 1123 and a marking location designation portion 1121 of the magnifying observation processing device set in the observation visual field setting region 1104 are overlapped with an image 1110 obtained by the scanning probe microscope (SPM) in FIG. 1 or 2 to be displayed inside the scanner movable range display portion 1002. Since the other configurations and functions of FIG. 11 are the same as the other configurations and functions of FIG. 10, repeated description thereof will be omitted.

First, a configuration example of the observation visual field setting region 1104 will be described. As illustrated in FIG. 11, to select a setting method, a manual and a template are provided in the observation visual field setting region 1104 to be selectable. In FIG. 11, a state where a template is selected (a black circle • mark) is illustrated. When the template is selected, a detail selection region 1105 is displayed. In the detail selection region 1105, an option for a visual field magnification of the magnifying observation processing device (here, the first scanning electron microscope SEM1) selected with a movement destination observation device is displayed. In this example, for the first scanning electron microscope SEM1, a template item of ×10k magnification and a template item of ×5k magnification are shown as a representative example, and a state where the template item of the ×10k magnification is selected (tick mark) is shown. When the template item is selected, an observation visual field 1123 of the first scanning electron microscope SEM1 is displayed for an aspect ratio in the scanner movable range display portion 1002 based on the aspect ratio of the observation visual field of the first scanning electron microscope SEM1. In this example, marking location designation portions 1121 are displayed at four corners of the observation visual field 1123. The marking location designation portions 1121 are configured to be selectable. In FIG. 11, as a representative example, the marking location designation portions 1121 of three corners are in a selected state (tick marks). Accordingly, for example, as illustrated in (a) of FIG. 7, positions at which the markers are disposed at three corners around the region of interest 1024 can be designated. A marker shape and the like are set by setting the list boxes 1005 to 1011 for the condition setting. When a marking start button is clicked after setting of the template item, selection of the marking location designation portion 1121, and the setting of the list boxes 1005 to 1011 for the condition setting, a marker with high visibility can be automatically formed at three corners around the region of interest 1024.

The template item is a template item of magnification but may be an aspect ratio of an observation visual field. The detail selection region 1105 may be configured such that a visual field magnification or a visual field aspect ratio in marker search of the magnifying observation processing device can be input.

In this way, since a position at which the marker is disposed can be visually designated while confirming the image 1110 and the marking location designation portion 1121 displayed in the scanner movable range display portion 1002, it is possible to provide an interface in which convenience for a user is improved.

In FIG. 11, the observation visual field 1124 described in the scanner movable range display portion 1002 exemplarily indicates an observation visual field of the second scanning electron microscope SEM2. The image 1110 may be considered to be an image obtained with the optical microscope 115 of the scanning probe microscope (SPM) in FIG. 1 or 2.

When the manual is selected, for example, an input of a predetermined item such as an input of visual field magnification of an observation visual field or an input of an aspect ratio of an observation visual field can be performed. The control unit 127 can perform calculation based on a value input to a predetermined item and perform similar display to FIG. 11 on the scanner movable range display portion 1002.

The marking location designation portion 1121 can be rephrased to indicate a location where a marker is formed and the observation visual field 1123 can be rephased to indicate an observation visual field considered as an observation visual field of the first scanning electron microscope SEM1.

In FIG. 11, a side between the marking location designation portions 1121 can also be selected. Accordingly, markers of sides 709, 710, and 711 illustrated in (i), (k), and (j) of FIG. 7 can be formed with shapes in which visibility is improved.

Although the embodiments of the present invention devised by the present inventors have been described specifically, the present invention is not limited to the foregoing embodiments and examples, but it is needless to say that various modification can be made.

### REFERENCE SIGNS LIST

101: scanning probe microscope (SPM) of sample scanning type
102: photodetector
103: laser beam
104: detector-side mirror
105: laser-side mirror
106: laser diode
107: bimorph piezoelectric element
108: cantilever
109: sample
110: sample table
111: sample scanner Z piezoelectric element
112: sample scanner X piezoelectric element
113: sample scanner Y piezoelectric element
114: needle
115: optical microscope
120: laser control circuit
121: bimorph driving circuit
122: XY piezoelectric driving circuit
123: signal amplification circuit
124: Z feedback circuit
125: signal processing unit
126: storage unit
127: control unit
128: monitor display unit
201: scanning probe microscope (SPM) of probe scanning type
211: probe scanner Z piezoelectric element
212: probe scanner X piezoelectric element
213: probe scanner Y piezoelectric element
214: sample stage
215: sample stage driving circuit
401: marking probe
402: sample
403: sample table
404: marker
405: region of interest
406: measurement visual field
411: column
412: sample stage
413: sample
414: detector
415: signal processing unit
416: observation visual field
417: observation visual field after adjustment of visual field position and angle
418: magnified observation visual field
511: column
512: sample stage
513: sample
514: detector
515: signal processing unit
516: observation visual field
517: column
518: observation visual field after alignment
519: magnified observation visual field
601: measurement visual field
602: column
603: marking probe
604: sample stage
605: detector
606: signal processing unit
607: electric measurement probe
608: ammeter
609: constant voltage source
701: cross marker
702: region of interest
703: observation visual field in marking search
704: cross (X type) marker
705: corner bracket (L-shaped) marker
706: observation visual field of 1:1 aspect ratio
707: observation visual field of 16:9 aspect ratio
708: observation visual field of 3:4 aspect ratio
709: short-side marker
710: long-side marker
711: short-side and long-side integrated marker
801: one-line marker
802: four-lines marker
803: eight-lines marker
811: weak tactile pressure marker
812: strong tactile pressure marker
813: plural-overwritten marker
821: asterisk marker
831: small-sized marker
832: large-sized marker
901: measurement probe needle position
902: measurement probe
903: marking probe
904: marking probe needle position
905: marking probe needle position deviation distance
906: marking probe after position deviation correction
1001: marking setting screen
1002: scanner movable range display portion
1003: marking condition display portion
1004: observation visual field setting button
1005: marker shape list box
1006: marker size list box
1007: marker interval list box
1008: number-of-markers list box
1009: drawing indentation amount list box
1010: drawing speed list box
1011: number-of-overwrites list box
1012: region-of-interest position display portion
1021: marking location
1022: observation visual field
1023: observation visual field
1024: region of interest
1110: SPM observation image display portion
1104: observation visual field setting region
1105: detail selection region
1121: marking location designation portion
1123: observation visual field
1124: observation visual field

1. A scanning probe microscope including a scanning unit that relatively scans a sample and a needle and observes the sample by scanning the sample and the needle, the scanning probe microscope comprising a control unit,
wherein the control unit is a magnifying observation processing device that acquires a region of interest obtained in a result of the scanning and then performs observation or processing or both the observation and the processing, and
wherein, based on information regarding the magnifying observation processing device separated from the scanning probe microscope, the control unit performs control such that a marker indicating at least a part of an outer edge of an observed or processed region is formed by specifying a region that is a region where a region observed or processed by the magnifying observation processing device contains the region of interest and is an observed or processed region where the region of interest is located at a scaling center when the region is observed with the magnifying observation processing device, and interacting the needle and the sample.

2. The scanning probe microscope according to claim 1,
wherein the marker is formed through the interaction of the needle and the sample, and
wherein a position at which the marker is formed is generated so that a rectangle is identical or similar to a visual field size when the magnifying observation processing device searches for the marker and the rectangle indicates at least one corner or side.

3. The scanning probe microscope according to claim 1, wherein the marker is disposed at a position which is not rotationally symmetric when a center of the region of interest is a rotational center.

4. The scanning probe microscope according to claim 1, wherein a visual field size or a visual field aspect ratio in marker search of the magnifying observation processing device is stored, and a disposition location condition of a marker appropriate for the visual field size is selectable and controllable.

5. The scanning probe microscope according to claim 1, wherein, when the marker is formed by a line, one or more of conditions of a direction of the line of the marker, a length of the line of the marker, a thickness of the line of the marker, the number of times the line of the marker is overwritten, a depth or height of the line of the marker, and a drawing speed of the line of the marker are changed.

6. The scanning probe microscope according to claim 1,
wherein the scanning unit is configured with a piezoelectric element, and
wherein, when the marker is formed, the predetermined marker is formed after scanning is performed a plurality of times in a condition that the marker is not formed by a space or the needle.

7. The scanning probe microscope according to claim 1,
wherein, in the scanning probe microscope, an observation needle and a marking needle are able to be exchanged or used together, and
wherein the scanning probe microscope further comprises means for correcting positional deviation between the observation needle and the marking needle.

8. The scanning probe microscope according to claim 1, further comprising a monitor display unit,
wherein the monitor display unit displays a marking setting screen including a scanner movable range display portion and a marking condition display portion,
wherein the marking setting screen is configured such that a visual field magnification or a visual field aspect ratio in the marker search of the magnifying observation processing device is inputtable,
wherein, based on an input of the visual field magnification or the visual field aspect ratio to the marking condition display portion, the scanner movable range display portion displays a rectangle identical or similar to a visual field size when the magnifying observation processing device searches for the marker, and displays a selectable marking location designation portion in a corner of the rectangle, and
wherein the marker is formed in the sample based on a selection state of the marking location designation portion.

9. A sample observation processing system comprising:
the scanning probe microscope according to claim 1; and
a magnifying observation processing device configured to perform observation or processing of the sample in which the region of interest is specified or both the observation and the processing,
wherein the sample observation processing system matches one or more of corners of a visual field of the magnifying observation processing device with the marker so that angles of the region of interest of the scanning probe microscope and an observed or processed region of the magnifying observation processing device are matched using the marker generated by the scanning probe microscope, increases a magnification of the magnifying observation processing device, and then performs observation or processing of the region of interest or both the observation and the processing.

10. The sample observation processing system according to claim 9, wherein one or a plurality of conductive probes or the scanning probe microscopes for electric measurement of a sample inside a sample chamber of a scanning electron microscope are provided, the region of interest is specified by one or both of the conductive probe and the scanning probe microscope, and the marker is formable.

11. An electric characteristic evaluation device that evaluates electric characteristics of a sample, the electric characteristic evaluation device comprising:
a conductive needle;
a driving unit configured to change a relative position relation between the sample and the needle;
an electric characteristic evaluation unit connected to the needle and configured to evaluate the electric characteristics of the sample; and
a charged particle beam irradiation unit configured to irradiate the sample with a charged particle beam,
wherein, by irradiating the sample with the charged particle beam while bringing the needle in contact with the sample, the electric characteristics of the sample are evaluated and a region of interest is specified on the basis of a result of the evaluation,
wherein a region that is a region containing the region of interest and is an observed or processed region where the region of interest is located at a scaling center when the region is observed with a magnifying observation processing device is specified, and
wherein a marker indicating at least a part of an outer edge of the observed or processed region is formed by interacting the needle and the sample.

12. An electric characteristic evaluation device that evaluates electric characteristics of a sample, the electric characteristic evaluation device comprising:
a conductive needle;
a driving unit configured to change a relative position relation between the sample and the needle;
an electric characteristic evaluation unit connected to the needle and configured to evaluate the electric characteristics of the sample; and
a charged particle beam irradiation unit configured to irradiate the sample with a charged particle beam,
wherein the needle is able to be brought into contact with the sample within a visual field of the charged particle beam irradiation unit,
wherein, by irradiating the sample with the charged particle beam while bringing the needle in contact with the sample, the electric characteristics of the sample are evaluated and a region of interest is specified on the basis of a result of the evaluation,
wherein a region that is a region containing the region of interest and is an observed or processed region where the region of interest is located at a scaling center when the region is observed with a magnifying observation processing device is specified, and
wherein a marker indicating at least a part of an outer edge of the observed or processed region is formed by interacting the needle and the sample.

13. The electric characteristic evaluation device according to claim 11, wherein observation or processing and both of the observation and the processing are performed on the region of interest of the sample of which electric characteristics are evaluated by the electric characteristic evaluation device.
